(19) United States
(12) Patent Application Publication
(10) Pub. No.: US 2001/0002067 A1
(43) Pub. Date: May 31, 2001

(54) Resin-encapsulated semiconductor device and method of forming the same

(75) Inventor: Kousuke Azuma, Tokyo (JP)

Correspondence Address: YOUNG & THOMPSON, 745 SOUTH 23RD STREET 2ND FLOOR, ARLINGTON, VA, 22202

(73) Assignee: NEC CORPORATION

(21) Appl. No.: 09/725,120

(22) Filed: Nov. 29, 2000

(30) Foreign Application Priority Data
Nov. 29, 1999 (JP) 11-337434

(51) Int. Cl. H01L 23/34

(52) U.S. Cl. 257/717; 257/713; 257/712

(57) ABSTRACT

The present invention provides a resin-encapsulated semiconductor device having inner leads and at least a heat spreader, wherein at least an electrical insulator is provided between the inner leads and the heat spreader, or wherein suspension pins for suspending an island mounting a semiconductor device are formed to have a lower level than the inner leads, or wherein the heat spreader has a fixing means for fixing the heat spreader over position, or wherein the heat spreader has an elevated center region having a light level than a peripheral region of the heat spreader.

### BACKGROUND OF THE INVENTION

The present invention relates to a resin-encapsulated semiconductor device and a method of forming the same, and more particularly to a resin-encapsulated semiconductor device with a heat spreader buried in a semiconductor package.

The semiconductor device in operating state generates a heat which may deteriorates characteristics or performances of the semiconductor device, for which reason it is necessary to allow a heat radiation from the semiconductor package. It has been known that a metal heat radiator plate or a heat spreader made of a highly heat conductivity is adhered on a lead frame, whereby the heat generated from the operating semiconductor device is transferred to entire parts of the package, so that the heat is radiated to atmosphere. In order to realize a certain cost down and increase applicability, the heat spreader is dropped into a cavity of dies for direct resin-molding, so that a lead frame mounted with a semiconductor device is placed in the dies before the resin encapsulation is carried out. This metal heat radiator plate is so called as drop-in-heat spreader.

FIG. 1A is a schematic perspective view illustrative of a conventional drop-in-heat spreader. FIG. 1B is a cross sectional elevation view illustrative of the conventional drop-in-heat spreader of FIG. 1A. FIG. 1C is a cross sectional elevation view illustrative of a resin-encapsulated semiconductor device with the conventional drop-in-heat spreader of FIGS. 1A and 1B. A drop-in-heat spreader 1 comprises a disk-shaped heat radiation plate 1a having four extension foots 1d which radially and downwardly extend from a circumferential part of the disk-shaped heat radiation plate 1a. The disk-shaped heat radiation plate 1a further has alternating alignments of slits 1b and ridged projections 1c, wherein the slits 1b and the ridged projections 1c extend in parallel to each other and are aligned alternatively. The resin-encapsulated semiconductor device shown in FIG. 1C has the following structure. An encapsulating-resin 10 encapsulates a semiconductor device 2, an island 6 on which the semiconductor device is mounted, inner leads 3, bonding wires 5 inter-connecting the semiconductor device 2 and the inner leads 3, and a heat spreader 1 having ridged projections 1c which are in contact with the island 6. Outer leads 4 extend from the inner leads 3, so that the encapsulating resin does not encapsulate the outer leads 4. The slits 1b are formed for allowing the resin to pass through the slits 1b in the resin-encapsulation process, thereby to prevent any displacement of the heat spreader. Further, the contact between the ridged projections 1c and the island 6 promotes the heat radiation. Some of the heat spreaders are free of any projections. A height of the extensions 1d is slightly smaller than a depth of the cavity of the dies.

FIGS. 2A and 2B are schematic perspective views illustrative of the conventional molding processes for forming the resin-molded semiconductor device.

With reference to FIG. 2A, a heat spreader 1 is dropped into each cavity 11a of a bottom die 11b which makes a pair with a top die 12, so that the heat spreader 1 is placed in the each cavity 11a. A lead frame 13, on which a semiconductor device is mounted, is placed on the bottom die 11.

With reference to FIG. 2B, the top die 12 is moved in a direction represented by an arrow mark so that the top die 12 is made close to the bottom die 11, whereby the top and bottom dies 12 and 11 are clamped. A resin is injected into the each cavity 11a for resin-encapsulation to the semiconductor device. A curing process for curing the resin is carried out. The lead frame is cut and shaped to complete the resin-molded semiconductor device as shown in FIG. 1C.

FIG. 3 is a cross sectional view illustrative of a resin-molded semiconductor device with a heat spreader which is displaced in injection of a molding resin which explains a problem caused by the conventional technique. When the resin is injected into the cavity for encapsulation to the semiconductor device 2 mounted on the island 6 which is supported over the heat spreader 1, the resin flow forces the heat spreader 1, so that the heat spreader 1 with the island 6 and the semiconductor device 2 is moved upwardly, whereby the projection of the heat spreader is made into contact with the inner lead 3. Since the heat spreader is made of a metal, a short circuit is then formed. This problem is caused by the following reasons. When the height of the extensions (foots) of the heat spreader 1 is compared to a distance between the upper surface of the heat spreader 1 to the island 6, the height of the extensions (foots) of the heat spreader 1 is much larger than the distance between the upper surface of the heat spreader 1 to the island 6, for which reason an amount of the resin 10 injected to the bottom space of the heat spreader 1 is much larger than an amount of the resin 10 injected to the inter-space between the upper surface of the heat spreader 1 and the island 6. Even the heat spreader 1 has the plural slits which allow the resin to pass through them, the heat spreader 1 is forced upwardly by the injected resin. If the island 6 for mounting the semiconductor device 2 is large, a suppressing down-force to the heat spreader is large, whereby the upward movement of the heat spreader 1 is suppressed. As a result, the contact between the heat spreader 1 an the inner lead 3 may be prevented. If the island 6 and the semiconductor device 2 are small, then the suppressing down-force to the heat spreader is small, whereby the upward movement of the heat spreader 1 is allows. As a result, the contact between the heat spreader 1 an the inner lead 3 may appear.

Even if the contact between the heat spreader 1 an the inner lead 3 does not appear, but if the heat spreader 1 is forced upwardly by the injection resin whereby the heat spreader 1 is tilted, then the heat radiation effect is deteriorated and the heat radiation properties are variable.

In the above circumstances, it had been required to develop a novel resin-encapsulated semiconductor device and method of forming the same free from the above problem.

### SUMMARY OF THE INVENTION

Accordingly, it is an object of the present invention to provide a novel resin-encapsulated semiconductor device free from the above problems.

It is a further object of the present invention to provide a novel resin-encapsulated semiconductor device with a heat spreader, which prevents the heat spreader from being displaced by a received force in upward direction from an injection resin, thereby preventing a contact between the heat spreader and an inner lead.

It is a still further object of the present invention to provide a novel resin-encapsulated semiconductor device with a heat spreader, which prevents the heat spreader from being displaced by a received force in upward direction from an injection resin, thereby preventing deterioration of a heat radiation effect of the heat spreader.

It is yet a further object of the present invention to provide a novel heat spreader free from the above problems.

It is further more object of the present invention to provide a novel heat spreader improved for preventing a displacement by a received force in upward direction from an injection resin, thereby preventing a contact between the heat spreader and an inner lead.

It is further more object of the present invention to provide a novel heat spreader improved for preventing a displacement by a received force in upward direction from an injection resin, thereby preventing deterioration of a heat radiation effect of the heat spreader.

The present invention provides a resin-encapsulated semiconductor device having inner leads and at least a heat spreader, wherein at least an electrical insulator is provided between the inner leads and the heat spreader.

The present invention also provides a resin-encapsulated semiconductor device having inner leads and at least a heat spreader, wherein suspension pins for suspending an island mounting a semiconductor device are formed to have a lower level than the inner leads.

The present invention also provides a resin-encapsulated semiconductor device having inner leads and at least a heat spreader, wherein the heat spreader has a fixing means for fixing the heat spreader over position.

The present invention also provides a resin-encapsulated semiconductor device having inner leads and at least a heat spreader, wherein the heat spreader has an elevated center region having a light level than a peripheral region of the heat spreader.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIG. 1A is a schematic perspective view illustrative of a conventional drop-in-heat spreader.

FIG. 1B is a cross sectional elevation view illustrative of the conventional drop-in-heat spreader of FIG. 1A.

FIG. 1C is a cross sectional elevation view illustrative of a resin-encapsulated semiconductor device with the conventional drop-in-heat spreader of FIGS. 1A and 1B.

FIGS. 2A and 2B are schematic perspective views illustrative of the conventional molding processes for forming the resin-molded semiconductor device.

FIG. 3 is a cross sectional view illustrative of a resin-molded semiconductor device with a heat spreader which is displaced in injection of a molding resin which explains a problem caused by the conventional technique.

FIG. 4 is a schematic perspective view illustrative of a novel drop-in-heat spreader to be used for a resin-encapsulated semiconductor device in a first embodiment in accordance with the present invention.

FIG. 5A is a plane view illustrative of a novel resin-encapsulated semiconductor device with the drop-in-heat spreader in a second embodiment in accordance with the present invention.

FIG. 5B is a cross sectional elevation view illustrative of the novel resin-encapsulated semiconductor device with the drop-in-heat spreader in a second embodiment in accordance with the present invention.

FIG. 6A is a plane view illustrative of a novel resin-encapsulated semiconductor device with the drop-in-heat spreader in a third embodiment in accordance with the present invention.

FIG. 6B is a cross sectional elevation view illustrative of the novel resin-encapsulated semiconductor device with the drop-in-heat spreader in a third embodiment in accordance with the present invention.

FIG. 7 is a schematic perspective view illustrative of a novel drop-in-heat spreader to be used for a resin-encapsulated semiconductor device in a fourth embodiment in accordance with the present invention.

FIG. 8 is a schematic perspective view illustrative of a novel drop-in-heat spreader to be used for a resin-encapsulated semiconductor device in a fifth embodiment in accordance with the present invention.

FIG. 9 is a schematic perspective view illustrative of a novel drop-in-heat spreader to be used for a resin-encapsulated semiconductor device in a sixth embodiment in accordance with the present invention.

FIG. 10A is a schematic perspective view illustrative of a novel drop-in-heat spreader to be used for a resin-encapsulated semiconductor device in a seventh embodiment in accordance with the present invention.

FIG. 10B is a cross sectional view illustrative of a novel drop-in-heat spreader to be used for a resin-encapsulated semiconductor device in a seventh embodiment in accordance with the present invention.

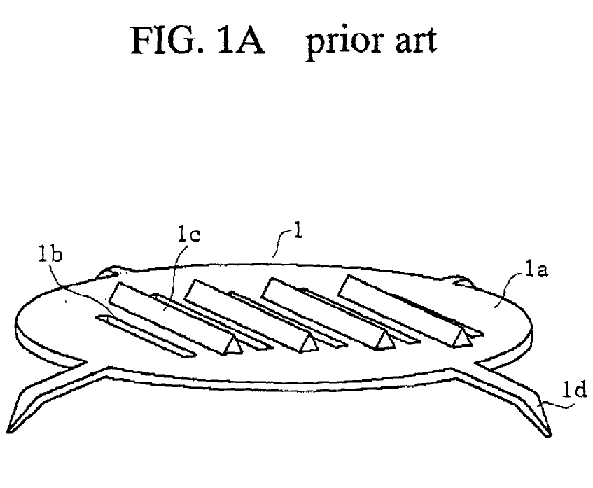

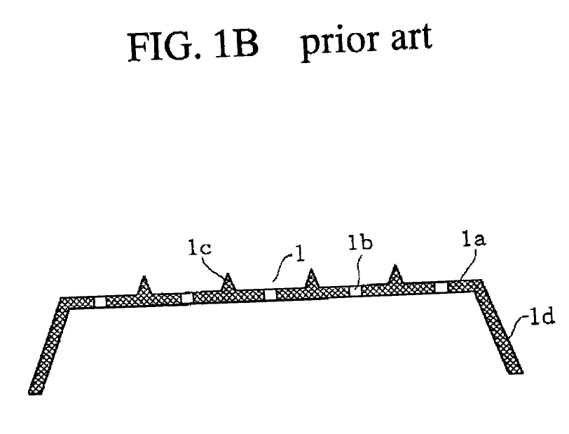

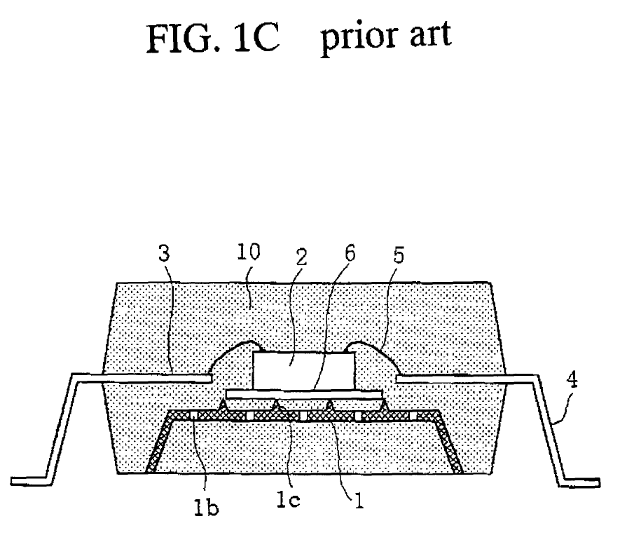

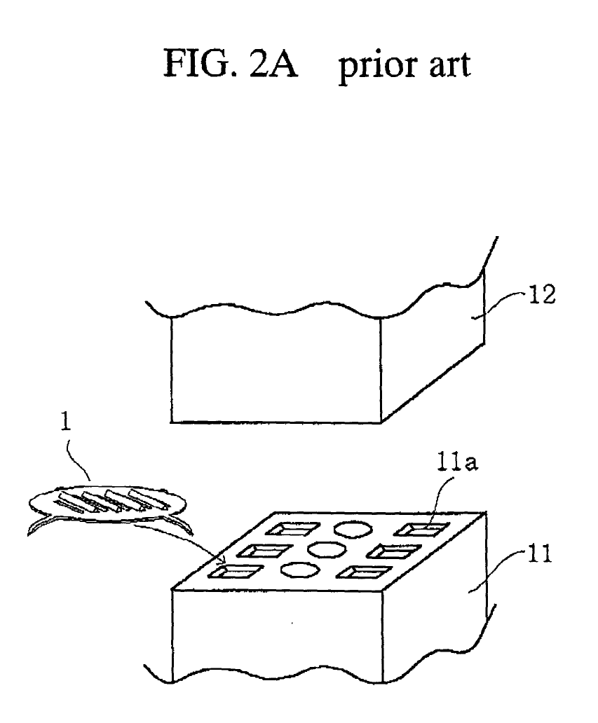

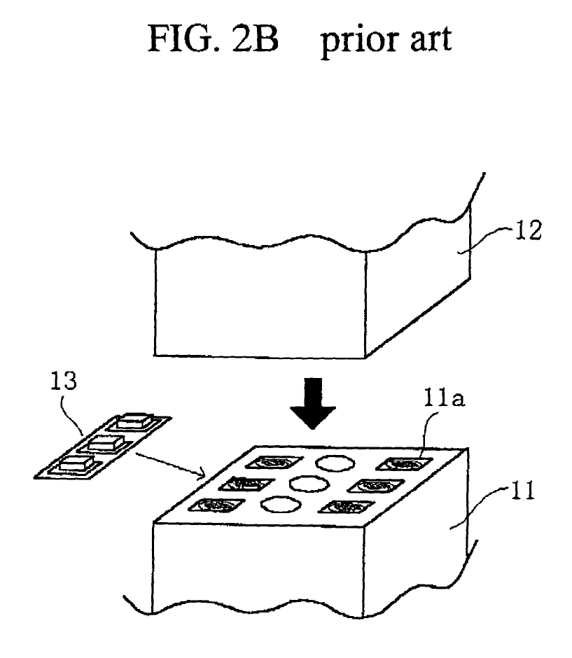

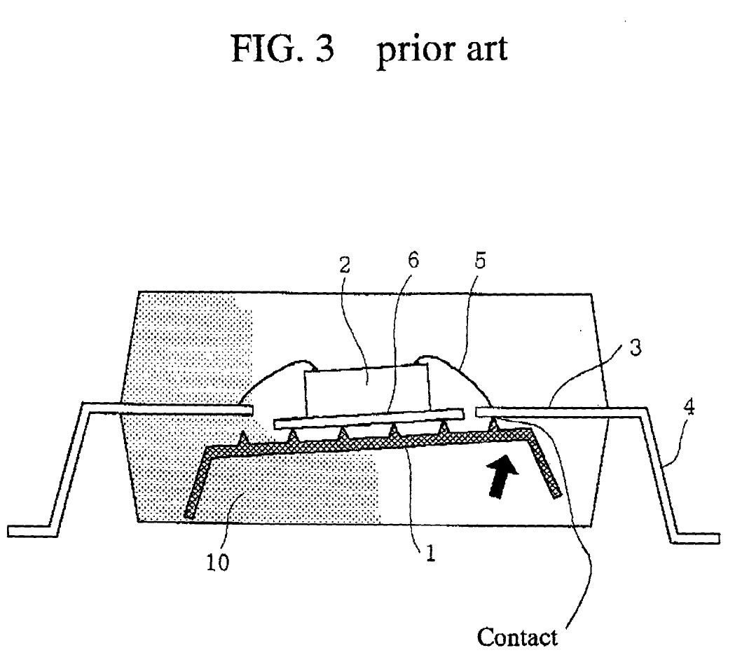

### DISCLOSURE OF THE INVENTION

The first present invention provides a resin-encapsulated semiconductor device having inner leads and at least a heat spreader, wherein at least an electrical insulator is provided between the inner leads and the heat spreader.

It is also preferable that the electrical insulator comprises a sheet-shaped insulator which is provided on an inside region of a bottom surface of each of the inner leads, and the inside region faces to a peripheral region of the heat spreader.

It is also preferable that the sheet-shaped insulator comprises a thermally stable and electrically insulative tape.

It is also preferable that the electrical insulator comprises a sheet-shaped insulator which is provided on at least a peripheral region of the heat spreader, and the peripheral region faces to an inside region of a bottom surface of each of the inner leads.

It is also preferable that the sheet-shaped insulator comprises a thermally stable and electrically insulative tape.

It is also preferable that the electrical insulator comprises: a first sheet-shaped insulator which is provided on an inside region of a bottom surface of each of the inner leads, and the inside region faces to a peripheral region of the heat spreader; and a second sheet-shaped insulator which is provided on at least the peripheral region of the heat spreader.

It is also preferable that the first sheet-shaped insulator comprises a thermally stable and electrically insulative tape.

It is also preferable that the second sheet-shaped insulator comprises a thermally stable and electrically insulative tape.

The second present invention provides a resin-encapsulated semiconductor device having inner leads and at least a heat spreader, wherein suspension pins for suspending an island mounting a semiconductor device are formed to have a lower level than the inner leads.

The third present invention provides a resin-encapsulated semiconductor device having inner leads and at least a heat spreader, wherein the heat spreader has a fixing means for fixing the heat spreader to a cavity of a die.

It is also preferable that the fixing means comprises an adhesive provided on a top of each of extension foots of the heat spreader.

It is also preferable that the adhesive comprises a thermosetting resin adhesive.

The fourth present invention provides a resin-encapsulated semiconductor device having inner leads and at least a heat spreader, wherein the heat spreader has a fixing means for fixing the heat spreader to an island, on which a semiconductor device is mounted.

It is also preferable that the fixing means comprises an adhesive provided on a top of each of projections of the heat spreader.

It is also preferable that the adhesive comprises a thermosetting resin adhesive.

It is also preferable that the fixing means comprises an adhesive provided on a planarized top surface of the heat spreader.

It is also preferable that the adhesive comprises a thermosetting resin adhesive.

The fifth present invention provides a resin-encapsulated semiconductor device having inner leads and at least a heat spreader, wherein the heat spreader has an elevated center region having a light level than a peripheral region of the heat spreader.

The sixth present invention provides a heat spreader for a resin-encapsulated semiconductor device having inner leads, wherein at least an electrical insulator is provided between the inner leads and the heat spreader.

It is also preferable that the electrical insulator comprises a sheet-shaped insulator which is provided on at least a peripheral region of the heat spreader, and the peripheral region faces to an inside region of a bottom surface of each of the inner leads.

It is also preferable that the sheet-shaped insulator comprises a thermally stable and electrically insulative tape.

The seventh present invention provides a heat spreader for a resin-encapsulated semiconductor device having inner leads, wherein the heat spreader has a fixing means for fixing the heat spreader to a cavity of a die.

It is also preferable that the fixing means comprises an adhesive provided on a top of each of extension foots of the heat spreader.

It is also preferable that the adhesive comprises a thermosetting resin adhesive.

The eighth present invention provides a heat spreader for a resin-encapsulated semiconductor device having inner leads, wherein the heat spreader has a fixing means for fixing the heat spreader to an island, on which a semiconductor device is mounted.

It is also preferable that the fixing means comprises an adhesive provided on a top of each of projections of the heat spreader.

It is also preferable that the adhesive comprises a thermosetting resin adhesive.

It is also preferable that the fixing means comprises an adhesive provided on a planarized top surface of the heat spreader.

It is also preferable that the adhesive comprises a thermosetting resin adhesive.

The ninth present invention provides a heat spreader for a resin-encapsulated semiconductor device having inner leads, wherein the heat spreader has an elevated center region having a light level than a peripheral region of the heat spreader.

The tenth present invention provides a lead frame having a semiconductor device mounted on an island and inner leads for a resin-encapsulated semiconductor device having inner leads, wherein at least an electrical insulator is provided an inside region of a bottom surface of each of the inner leads, and the inside region faces to a peripheral region of the heat spreader.

It is also preferable that the sheet-shaped insulator comprises a thermally stable and electrically insulative tape.

The eleventh present invention provides a lead frame having a semiconductor device mounted on an island and inner leads for a resin-encapsulated semiconductor device having inner leads, wherein suspension pins for suspending the island are formed to have a lower level than the inner leads.

### PREFERRED EMBODIMENT

FIRST EMBODIMENT:

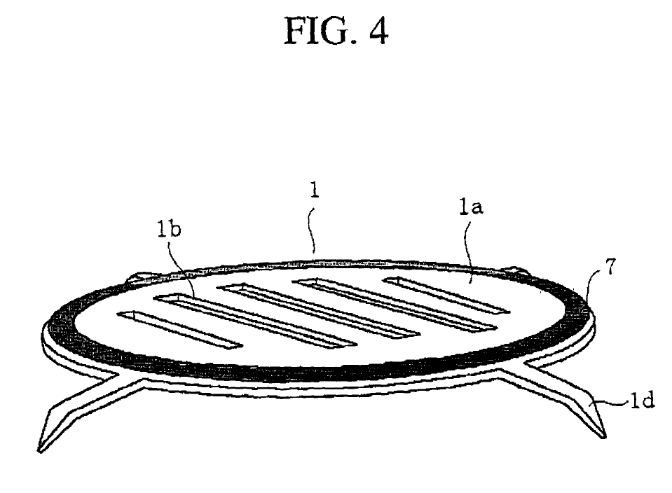

A first embodiment according to the present invention will be described in detail with reference to the drawings. FIG. 4 is a schematic perspective view illustrative of a novel drop-in-heat spreader to be used for a resin-encapsulated semiconductor device in a first embodiment in accordance with the present invention. A drop-in-heat spreader 1 comprises a disk-shaped heat radiation plate 1 a having four extension foots 1d which radially and downwardly extend from a circumferential part of the disk-shaped heat radiation plate 1a. The disk-shaped heat radiation plate 1a further has an alignment of slits 1b. Further, a thermally stable tape 7 is provided on a circumferential region on an upper surface of the disk-shaped heat radiation plate 1a. The thermally stable tape 7 is electrically insulative.

If the above novel heat spreader is applied to the resin-encapsulated semiconductor device, the following effects can be obtained. The thermally stable tape 7 is adhered on the upper surface of the disk-shaped heat radiation plate 1a of the heat spreader 1. The heat spreader 1 is dropped into the cavity of the bottom die. A lead frame, on which a semiconductor device is mounted, is placed on the bottom die. A top die is moved so that the top die is made close to the bottom die, whereby the top and bottom dies are clamped. A resin is injected into the each cavity for resin-encapsulation to the semiconductor device. A curing process for curing the resin is carried out. The lead frame is cut and shaped to complete the resin-molded semiconductor device.

When the resin is injected into the cavity for encapsulation to the semiconductor device mounted on the island which is supported over the heat spreader 1, the resin flow forces the heat spreader 1, so that the heat spreader 1 with the island and the semiconductor device is moved upwardly, whereby the thermally stable tape 7 covering the heat spreader is made into contact with the inner lead. Since the thermally stable tape 7 is electrically insulative and the thermally stable tape 7 isolates the heat spreader 1 from the inner lead, whereby no short circuit is formed between the inner lead and the heat spreader. The height of the extension foots 1d of the heat spreader 1 is much larger than the distance between the upper surface of the heat spreader 1 to the island, for which reason an amount of the resin injected to the bottom space of the heat spreader 1 is much larger than an amount of the resin injected to the inter-space between the upper surface of the heat spreader 1 and the island. Even the heat spreader 1 has the plural slits 1b which allow the resin to pass through them, the heat spreader 1 is forced upwardly by the injected resin, whereby the upward movement of the heat spreader 1 is allows. As a result, the contact between the thermally stable tape 7 and the inner lead may appear, but the thermally stable tape 7 electrically isolates the heat spreader 1 from the inner lead, whereby no short circuit is formed between the heat spreader 1 and the inner lead.

In this embodiment, the head spreader 1 is free of any projections such as ridged projections. As a modification, it is, however, possible for obtaining the effect of the present invention that the head spreader 1 has the ridged projections.

In this embodiment, the heat spreader 1 has a disk-shape. As a modification, it is possible for obtaining the effect of the present invention that the heat spreader 1 has a different shape from the disk-shape, for example, rectangle-shape. It is further possible for obtaining the effect of the present invention to modify the shape of the splits 1b of the heat spreader and also the shape of the ridge, if provided.

In this embodiment, the suspension pins 8 are provided at four corners of the island 6. As a modification, it is possible for obtaining the effect of the present invention that the suspension pins 8 are provided at different parts of the island 6 from the four corners.

SECOND EMBODIMENT:

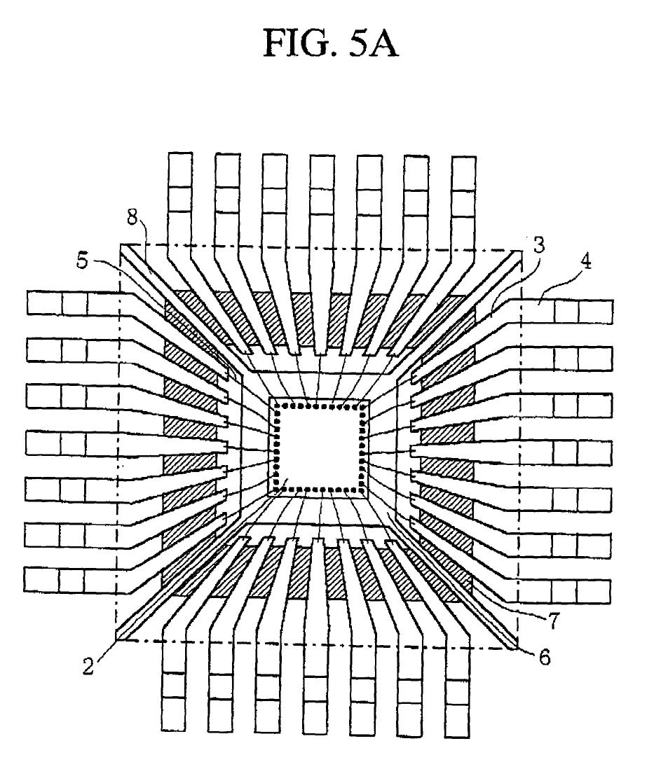

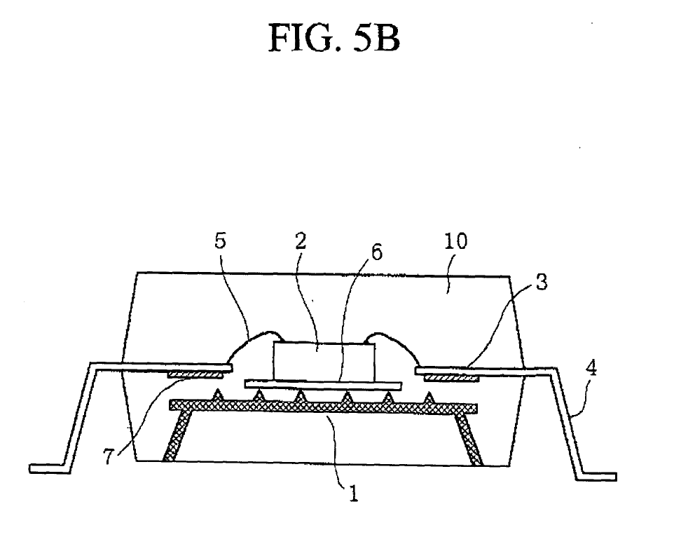

A second embodiment according to the present invention will be described in detail with reference to the drawings. FIG. 5A is a plane view illustrative of a novel resin-encapsulated semiconductor device with the drop-in-heat spreader in a second embodiment in accordance with the present invention. FIG. 5B is a cross sectional elevation view illustrative of the novel resin-encapsulated semiconductor device with the drop-in-heat spreader in a second embodiment in accordance with the present invention. A drop-in-heat spreader 1 comprises a disk-shaped heat radiation plate la having four extension foots 1d which radially and downwardly extend from a circumferential part of the disk-shaped heat radiation plate 1a. The disk-shaped heat radiation plate 1a further has alternating alignments of slits 1b and ridged projections 1c, wherein the slits and the ridged projections extend in parallel to each other and are aligned alternatively. An encapsulating-resin 10 encapsulates a semiconductor device 2, an island 6 on which the semiconductor device 2 is mounted, inner leads 3, bonding wires 5 inter-connecting the semiconductor device 2 and the inner leads 3, suspension pins 8 for suspending the island 6, and a heat spreader 1 having ridged projections which are in contact with the island 6. Outer leads 4 extend from the inner leads 3, so that the encapsulating resin 10 does not encapsulate the outer leads 4. Further, the contact between the ridged projections and the island promotes the heat radiation. A height of the extension foots is slightly smaller than a depth of the cavity of the dies. Further, in accordance with this second embodiment, thermally stable tapes 7 are adhered on bottom surfaces of the inner leads 3.

The molding processes for forming the resin-molded semiconductor device will be described. The heat spreader 1 is dropped into each cavity of a bottom die which makes a pair with a top die, so that the heat spreader 1 is placed in the each cavity. A lead frame, on which a semiconductor device 2 is mounted, is placed on the bottom die. The top die is moved so that the top die is made close to the bottom die, whereby the top and bottom dies are clamped. A resin is injected into the each cavity for resin-encapsulation to the semiconductor device. A curing process for curing the resin is carried out. The lead frame is cut and shaped to complete the resin-molded semiconductor device as shown in FIG. 5B.

When the resin is injected into the cavity for encapsulation to the semiconductor device 2 mounted on the island 6 which is supported over the heat spreader 1, the resin flow forces the heat spreader 1, so that the heat spreader 1 with the island 6 and the semiconductor device 2 is moved upwardly, whereby the projection of the heat spreader or the circumferential part of the heat spreader is made into contact with the thermally stable tape 7 which covers the inner lead 3. Since the thermally stable tape 7 is electrically insulative and the thermally stable tape 7 isolates the inner lead 3 from the heat spreader 1, whereby no short circuit is formed between the inner lead 3 and the heat spreader 1. The height of the extension foots 1d of the heat spreader 1 is much larger than the distance between the upper surface of the heat spreader 1 to the island, for which reason an amount of the resin injected to the bottom space of the heat spreader 1 is much larger than an amount of the resin injected to the inter-space between the upper surface of the heat spreader 1 and the island 6. Even the heat spreader 1 has the plural slits 1b which allow the resin to pass through them, the heat spreader 1 is forced upwardly by the injected resin, whereby the upward movement of the heat spreader 1 is allows. As a result, the contact between the thermally stable tape 7 and the heat spreader 1 may appear, but the thermally stable tape 7 electrically isolates the heat spreader 1 from the inner lead 3, whereby no short circuit is formed between the heat spreader 1 and the inner lead 3.

In this embodiment, the head spreader 1 has the ridged projections. As a modification, it is, however, possible for obtaining the effect of the present invention that the head spreader 1 is free of any projections such as ridged projections.

In this embodiment, the heat spreader 1 has a disk-shape. As a modification, it is possible for obtaining the effect of the present invention that the heat spreader 1 has a different shape from the disk-shape, for example, rectangle-shape. It is further possible for obtaining the effect of the present invention to modify the shape of the splits 1b of the heat spreader and also the shape of the ridge, if provided.

In this embodiment, the suspension pins 8 are provided at four corners of the island 6. As a modification, it is possible for obtaining the effect of the present invention that the suspension pins 8 are provided at different parts of the island 6 from the four corners.

THIRD EMBODIMENT:

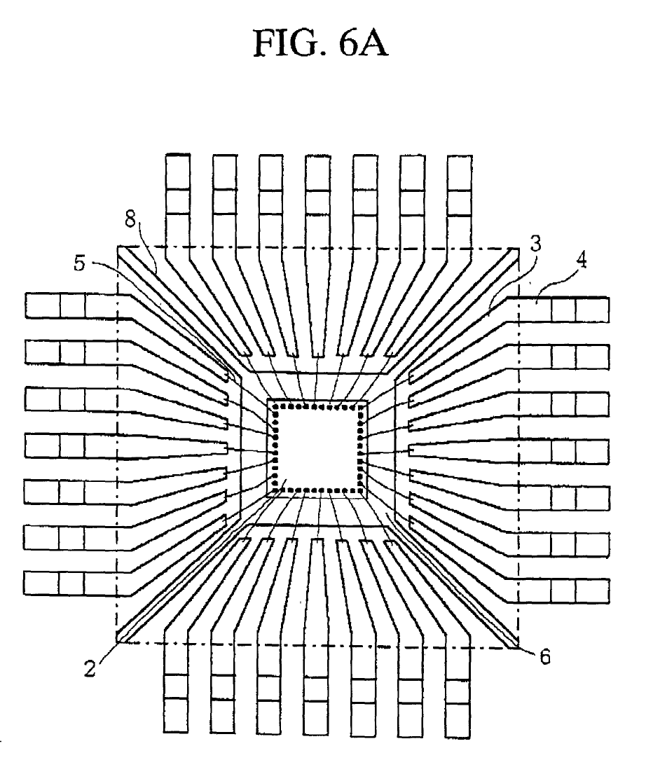

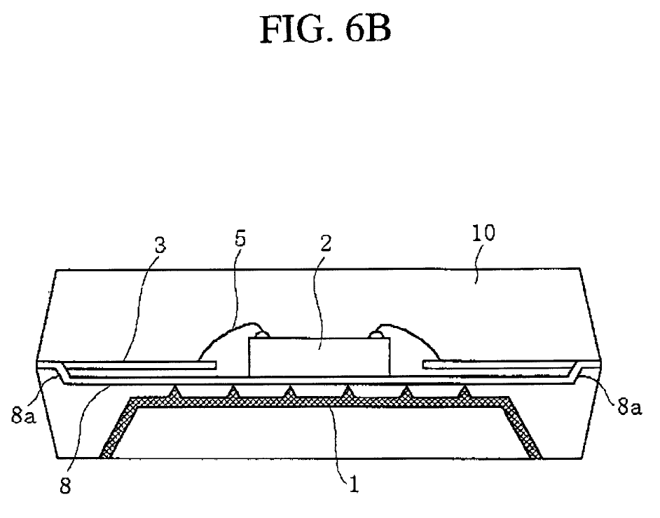

A third embodiment according to the present invention will be described in detail with reference to the drawings. FIG. 6A is a plane view illustrative of a novel resin-encapsulated semiconductor device with the drop-in-heat spreader in a third embodiment in accordance with the present invention. FIG. 6B is a cross sectional elevation view illustrative of the novel resin-encapsulated semiconductor device with the drop-in-heat spreader in a third embodiment in accordance with the present invention. A drop-in-heat spreader 1 comprises a disk-shaped heat radiation plate 1a having four extension foots 1d which radially and downwardly extend from a circumferential part of the disk-shaped heat radiation plate 1a. The disk-shaped heat radiation plate 1a further has alternating alignments of slits 1b and ridged projections 1c, wherein the slits and the ridged projections extend in parallel to each other and are aligned alternatively. An encapsulating-resin 10 encapsulates a semiconductor device 2, an island 6 on which the semiconductor device 2 is mounted, inner leads 3, bonding wires 5 inter-connecting the semiconductor device 2 and the inner leads 3, suspension pins 8 for suspending the island 6, and a heat spreader 1 having ridged projections which are in contact with the island 6. The suspension pins 8 have bent portions 8a, so that the suspension pins 8 and the island 6 suspended by the suspension pins 8 have a lower level than the bottom surface of the inner leads 3. The suspension pins 8 have the same potential as the island 6 on which the semiconductor device 2 is mounted. Outer leads 4 extend from the inner leads 3, so that the encapsulating resin 10 does not encapsulate the outer leads 4. Further, the contact between the ridged projections and the island promotes the heat radiation. A height of the extension foots is slightly smaller than a depth of the cavity of the dies.

The molding processes for forming the resin-molded semiconductor device will be described. The heat spreader 1 is dropped into each cavity of a bottom die which makes a pair with a top die, so that the heat spreader 1 is placed in the each cavity. A lead frame, on which a semiconductor device 2 is mounted, is placed on the bottom die. The top die is moved so that the top die is made close to the bottom die, whereby the top and bottom dies are clamped. A resin is injected into the each cavity for resin-encapsulation to the semiconductor device. A curing process for curing the resin is carried out. The lead frame is cut and shaped to complete the resin-molded semiconductor device as shown in FIG. 6B.

When the resin is injected into the cavity for encapsulation to the semiconductor device 2 mounted on the island 6 which is supported over the heat spreader 1, the resin flow forces the heat spreader 1, so that the heat spreader 1 with the island 6 and the semiconductor device 2 is moved upwardly, whereby the projection of the heat spreader 1 is made into contact with the suspension pins 8 which have the lower level than the inner lead 3. Since the suspension pins 8 have the same potential as the island 6, for which reason contact between the heat spreader 1 and the suspension pins 8 raises no problem. Namely, the suspension pins 8 isolates the inner lead 3 from the heat spreader 1, whereby no short circuit is formed between the inner lead 3 and the heat spreader 1. The height of the extension foots 1d of the heat spreader 1 is much larger than the distance between the upper surface of the heat spreader 1 to the island, for which reason an amount of the resin injected to the bottom space of the heat spreader 1 is much larger than an amount of the resin injected to the inter-space between the upper surface of the heat spreader 1 and the island 6. Even the heat spreader 1 has the plural slits 1b which allow the resin to pass through them, the heat spreader 1 is forced upwardly by the injected resin, whereby the upward movement of the heat spreader 1 is allows. As a result, the contact between the suspension pins 8 and the heat spreader 1 may appear, but the suspension pins 8 electrically isolates the heat spreader 1 from the inner lead 3, whereby no short circuit is formed between the heat spreader 1 and the inner lead 3.

In this embodiment, the head spreader 1 has the ridged projections. As a modification, it is, however, possible for obtaining the effect of the present invention that the head spreader 1 is free of any projections such as ridged projections.

In this embodiment, the heat spreader 1 has a disk-shape. As a modification, it is possible for obtaining the effect of the present invention that the heat spreader 1 has a different shape from the disk-shape, for example, rectangle-shape. It is further possible for obtaining the effect of the present invention to modify the shape of the splits 1b of the heat spreader and also the shape of the ridge, if provided.

In this embodiment, the suspension pins 8 are provided at four corners of the island 6. As a modification, it is possible for obtaining the effect of the present invention that the suspension pins 8 are provided at different parts of the island 6 from the four corners.

FOURTH EMBODIMENT:

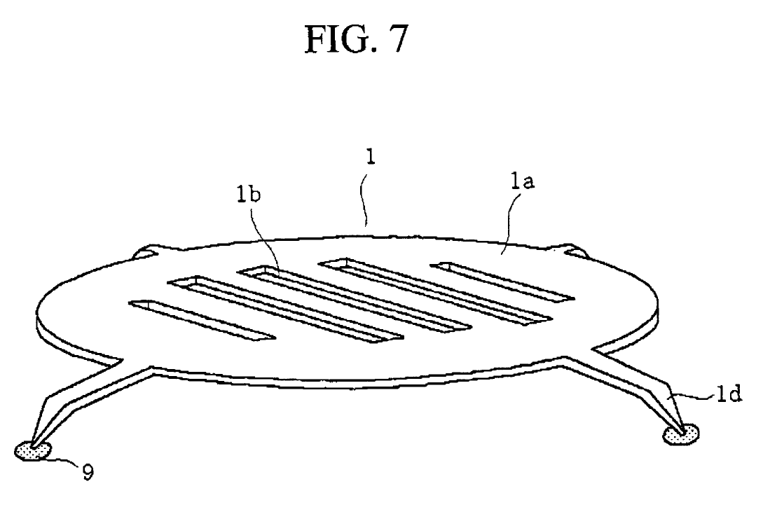

A fourth embodiment according to the present invention will be described in detail with reference to the drawings. FIG. 7 is a schematic perspective view illustrative of a novel drop-in-heat spreader to be used for a resin-encapsulated semiconductor device in a fourth embodiment in accordance with the present invention. A drop-in-heat spreader 1 comprises a disk-shaped heat radiation plate 1a having four extension foots 1d which radially and downwardly extend from a circumferential part of the disk-shaped heat radiation plate 1a. The disk-shaped heat radiation plate 1a further has an alignment of slits 1b. Further, a thermo-setting resin adhesive agent 9 is provided on a top of each of the extension foots 1d of the heat spreader 1.

If the above novel heat spreader is applied to the resin-encapsulated semiconductor device, the following effects can be obtained. The thermo-setting resin adhesive agent 9 provided on the top of each of the extension foots 1d of the heat spreader 1 is adhered on a bottom of the cavity of the bottom die when the heat spreader 1 is dropped into the cavity of the bottom die. A lead frame, on which a semiconductor device is mounted, is placed on the bottom die. A top die is moved so that the top die is made close to the bottom die, whereby the top and bottom dies are clamped. A resin is injected into the each cavity for resin-encapsulation to the semiconductor device. A curing process for curing the resin is carried out. The lead frame is cut and shaped to complete the resin-molded semiconductor device.

When the resin is injected into the cavity for encapsulation to the semiconductor device mounted on the island which is supported over the heat spreader 1, the resin flow forces the heat spreader 1. However, the thermo-setting resin adhesive agent 9 provided on the top of each of the extension foots 1 d of the heat spreader 1 is surely adhered on the bottom of the cavity of the bottom die, whereby the heat spreader 1 is secured or fixed to the bottom of the cavity of the bottom die by the thermo-setting resin adhesive agent 9 provided on the top of each of the extension foots 1d of the heat spreader 1, so that the heat spreader 1 with the island and the semiconductor device is not moved upwardly, whereby the heat spreader 1 remains separated from the inner lead, and no short circuit is formed between the inner lead and the heat spreader 1. Further, even the heat spreader 1 is forced upwardly by the injection resin, the heat spreader 1 is securely fixed to the bottom of the cavity of the bottom die, whereby the heat spreader 1 is prevented from being tilted by the thermo-setting resin adhesive agent 9 provided on the top of each of the extension foots 1d of the heat spreader 1. As a result, the heat radiation effect is not deteriorated and the heat radiation properties are not variable. The height of the extension foots 1d of the heat spreader 1 is much larger than the distance between the upper surface of the heat spreader 1 to the island, for which reason an amount of the resin injected to the bottom space of the heat spreader 1 is much larger than an amount of the resin injected to the inter-space between the upper surface of the heat spreader 1 and the island. Even the heat spreader 1 has the plural slits 1b which allow the resin to pass through them, the heat spreader 1 is forced upwardly by the injected resin. However, the thermo-setting resin adhesive agent 9 provided on the top of each of the extension foots 1d of the heat spreader 1 is surely adhered on the bottom of the cavity of the bottom die, whereby the heat spreader 1 is secured or fixed to the bottom of the cavity of the bottom die by the thermo-setting resin adhesive agent 9 provided on the top of each of the extension foots 1d of the heat spreader 1, so that the heat spreader 1 with the island and the semiconductor device is not moved upwardly, whereby the heat spreader 1 remains separated from the inner lead, and no short circuit is formed between the inner lead and the heat spreader 1. Further, even the heat spreader 1 is forced upwardly by the injection resin, the heat spreader 1 is securely fixed to the bottom of the cavity of the bottom die, whereby the heat spreader 1 is prevented from being tilted by the thermo-setting resin adhesive agent 9 provided on the top of each of the extension foots 1d of the heat spreader 1. As a result, the heat radiation effect is not deteriorated and the heat radiation properties are not variable. Furthermore, the thermo-setting resin adhesive agent 9 remains in the molded resin 10 but does not reside on the cavity of the die.

In this embodiment, the head spreader 1 is free of any projections such as ridged projections. As a modification, it is, however, possible for obtaining the effect of the present invention that the head spreader 1 has the ridged projections.

In this embodiment, the heat spreader 1 applied with the thermosetting resin adhesive agent 9, and the applied thermosetting resin adhesive agent is thermo-set before the lead frame mounted with the semiconductor device thereon is then placed over the bottom die prior to the resin injection process. As a modification, it is, however, possible for obtaining the effect of the present invention that the heat spreader 1 applied with the thermosetting resin adhesive agent 9, and subsequently the lead frame mounted with the semiconductor device thereon is placed over the bottom die before the thermosetting process of the applied thermosetting resin adhesive agent is completed prior to the resin injection process.

In this embodiment, the heat spreader 1 has a disk-shape. As a modification, it is possible for obtaining the effect of the present invention that the heat spreader 1 has a different shape from the disk-shape, for example, rectangle-shape. It is further possible for obtaining the effect of the present invention to modify the shape of the splits 1b of the heat spreader and also the shape of the ridge, if provided.

In this embodiment, the suspension pins 8 are provided at four corners of the island 6. As a modification, it is possible for obtaining the effect of the present invention that the suspension pins 8 are provided at different parts of the island 6 from the four corners.

FIFTH EMBODIMENT:

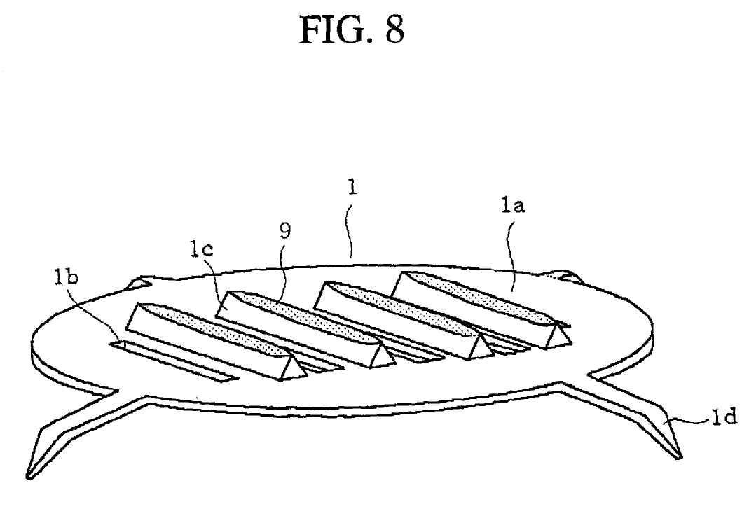

A fifth embodiment according to the present invention will be described in detail with reference to the drawings. FIG. 8 is a schematic perspective view illustrative of a novel drop-in-heat spreader to be used for a resin-encapsulated semiconductor device in a fifth embodiment in accordance with the present invention. A drop-in-heat spreader 1 comprises a disk-shaped heat radiation plate 1a having four extension foots 1d which radially and downwardly extend from a circumferential part of the disk-shaped heat radiation plate 1a. The disk-shaped heat radiation plate 1a further has alternating alignment of slits 1b and projection ridges 1c which extend in parallel to each other. Each of the projection ridges 1c has a planarized top surface on which a thermo-setting resin adhesive agent 9 is provided. Namely, the thermo-setting resin adhesive agent 9 is provided on the planarized top surface of each of the projection ridges 1c of the heat spreader 1.

If the above novel heat spreader is applied to the resin-encapsulated semiconductor device, the following effects can be obtained. The heat spreader 1 is dropped into the cavity of the bottom die. The thermo-setting resin adhesive agent 9 provided on the planarized top surface of each of the projection ridges 1c of the heat spreader 1 is adhered on a bottom surface of the island, on which a semiconductor device is mounted, is placed on the bottom die. A top die is moved so that the top die is made close to the bottom die, whereby the top and bottom dies are clamped. A resin is injected into the each cavity for resin-encapsulation to the semiconductor device. A curing process for curing the resin is carried out. The lead frame is cut and shaped to complete the resin-molded semiconductor device.

When the resin is injected into the cavity for encapsulation to the semiconductor device mounted on the island which is supported over the heat spreader 1, the resin flow forces the heat spreader 1. However, the thermo-setting resin adhesive agent 9 provided on the planarized top surface of each of the projection ridges 1c of the heat spreader 1 is adhered on the bottom surface of the island, whereby the heat spreader 1 is secured or fixed to the island by the thermo-setting resin adhesive agent 9 provided on the planarized top surface of each of the projection ridges 1c of the heat spreader 1, so that the heat spreader 1 with the island and the semiconductor device is controlled from being moved upwardly, whereby the heat spreader 1 remains separated from the inner lead, and no short circuit is formed between the inner lead and the heat spreader 1. Further, even the heat spreader 1 is forced upwardly by the injection resin, the heat spreader 1 is fixed to the island, whereby a large tilting of the heat spreader 1 is controlled by the thermo-setting resin adhesive agent 9 provided on the planarized top surface of each of the projection ridges 1c of the heat spreader 1. As a result, the heat radiation effect is not deteriorated and the heat radiation properties are not variable. The height of the extension foots 1d of the heat spreader 1 is much larger than the distance between the upper surface of the heat spreader 1 to the island, for which reason an amount of the resin injected to the bottom space of the heat spreader 1 is much larger than an amount of the resin injected to the inter-space between the upper surface of the heat spreader 1 and the island. Even the heat spreader 1 has the plural slits 1b which allow the resin to pass through them, the heat spreader 1 is forced upwardly by the injected resin. However, the thermo-setting resin adhesive agent 9 provided on the planarized top surface of each of the projection ridges 1c of the heat spreader 1 is surely adhered on the island, whereby the heat spreader 1 is secured or fixed to the island by the thermo-setting resin adhesive agent 9 provided on the planarized top surface of each of the projection ridges 1c of the heat spreader 1, so that the heat spreader 1 with the island and the semiconductor device is not largely moved upwardly, whereby the heat spreader 1 remains separated from the inner lead, and no short circuit is formed between the inner lead and the heat spreader 1. Further, even the heat spreader 1 is forced upwardly by the injection resin, the heat spreader 1 is securely fixed to the island by the thermo-setting resin adhesive agent 9 provided on the planarized top surface of each of the projection ridges 1c of the heat spreader 1, whereby the heat spreader 1 is prevented from being tilted by the thermo-setting resin adhesive agent 9 provided on the planarized top surface of each of the projection ridges 1c of the heat spreader 1. As a result, the heat radiation effect is not deteriorated and the heat radiation properties are not variable. Furthermore, the thermo-setting resin adhesive agent 9 remains in the molded resin 10 but does not reside on the cavity of the die.

In this embodiment, the heat spreader 1 applied with the thermosetting resin adhesive agent 9, and the applied thermosetting resin adhesive agent is thermo-set before the lead frame mounted with the semiconductor device thereon is then placed over the bottom die prior to the resin injection process. As a modification, it is, however, possible for obtaining the effect of the present invention that the heat spreader 1 applied with the thermosetting resin adhesive agent 9, and subsequently the lead frame mounted with the semiconductor device thereon is placed over the bottom die before the thermosetting process of the applied thermosetting resin adhesive agent is completed prior to the resin injection process.

In this embodiment, the heat spreader 1 has a disk-shape. As a modification, it is possible for obtaining the effect of the present invention that the heat spreader 1 has a different shape from the disk-shape, for example, rectangle-shape. It is further possible for obtaining the effect of the present invention to modify the shape of the splits 1b of the heat spreader and also the shape of the ridge, if provided.

In this embodiment, the suspension pins 8 are provided at four corners of the island 6. As a modification, it is possible for obtaining the effect of the present invention that the suspension pins 8 are provided at different parts of the island 6 from the four corners.

SIXTH EMBODIMENT:

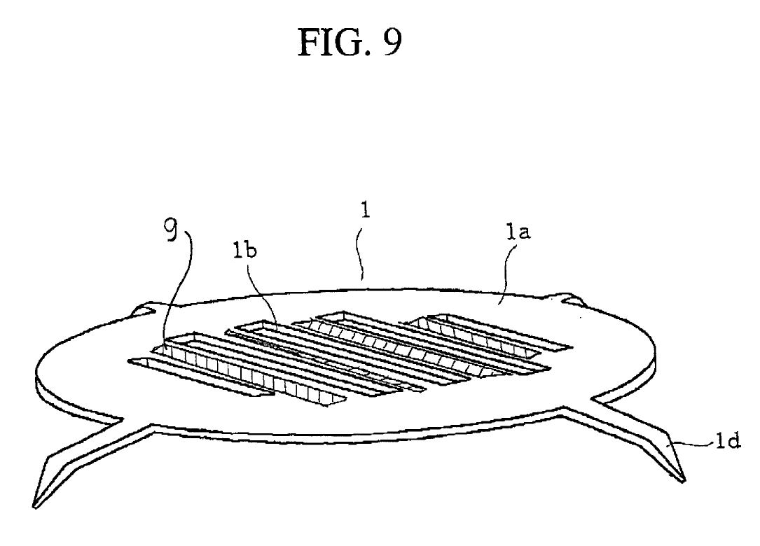

A sixth embodiment according to the present invention will be described in detail with reference to the drawings. FIG. 9 is a schematic perspective view illustrative of a novel drop-in-heat spreader to be used for a resin-encapsulated semiconductor device in a sixth embodiment in accordance with the present invention. A drop-in-heat spreader 1 comprises a disk-shaped heat radiation plate la having four extension foots 1d which radially and downwardly extend from a circumferential part of the disk-shaped heat radiation plate 1a. The disk-shaped heat radiation plate 1a further has alternating alignment of slits 1b which extend in parallel to each other. A thermo-setting resin adhesive agent 9 is provided on the planarized top surface of the disk-shaped heat radiation plate 1a of the heat spreader 1.

If the above novel heat spreader is applied to the resin-encapsulated semiconductor device, the following effects can be obtained. The heat spreader 1 is dropped into the cavity of the bottom die. The thermo-setting resin adhesive agent 9 provided on the planarized top surface of the disk-shaped heat radiation plate 1a of the heat spreader 1 is adhered on a bottom surface of the island, on which a semiconductor device is mounted, is placed on the bottom die. A top die is moved so that the top die is made close to the bottom die, whereby the top and bottom dies are clamped. A resin is injected into the each cavity for resin-encapsulation to the semiconductor device. A curing process for curing the resin is carried out. The lead frame is cut and shaped to complete the resin-molded semiconductor device.

When the resin is injected into the cavity for encapsulation to the semiconductor device mounted on the island which is supported over the heat spreader 1, the resin flow forces the heat spreader 1. However, the thermo-setting resin adhesive agent 9 provided on the planarized top surface of the disk-shaped heat radiation plate 1a of the heat spreader 1 is adhered on the bottom surface of the island, whereby the heat spreader 1 is secured or fixed to the island by the thermo-setting resin adhesive agent 9 provided on the planarized top surface of the disk-shaped heat radiation plate 1a of the heat spreader 1, so that the heat spreader 1 with the island and the semiconductor device is controlled from being moved upwardly, whereby the heat spreader 1 remains separated from the inner lead, and no short circuit is formed between the inner lead and the heat spreader 1. Further, even the heat spreader 1 is forced upwardly by the injection resin, the heat spreader 1 is fixed to the island, whereby a large tilting of the heat spreader 1 is controlled by the thermo-setting resin adhesive agent 9 provided on the planarized top surface of the disk-shaped heat radiation plate 1a of the heat spreader 1. As a result, the heat radiation effect is not deteriorated and the heat radiation properties are not variable. The height of the extension foots 1d of the heat spreader 1 is much larger than the distance between the upper surface of the heat spreader 1 to the island, for which reason an amount of the resin injected to the bottom space of the heat spreader 1 is much larger than an amount of the resin injected to the inter-space between the upper surface of the heat spreader 1 and the island. Even the heat spreader 1 has the plural slits 1b which allow the resin to pass through them, the heat spreader 1 is forced upwardly by the injected resin. However, the thermo-setting resin adhesive agent 9 provided on the planarized top surface of the disk-shaped heat radiation plate 1a of the heat spreader 1 is surely adhered on the island, whereby the heat spreader 1 is secured or fixed to the island by the thermo-setting resin adhesive agent 9 provided on the planarized top surface of the disk-shaped heat radiation plate 1a of the heat spreader 1, so that the heat spreader 1 with the island and the semiconductor device is not largely moved upwardly, whereby the heat spreader 1 remains separated from the inner lead, and no short circuit is formed between the inner lead and the heat spreader 1. Further, even the heat spreader 1 is forced upwardly by the injection resin, the heat spreader 1 is securely fixed to the island by the thermo-setting resin adhesive agent 9 provided on the planarized top surface of the disk-shaped heat radiation plate 1a of the heat spreader 1, whereby the heat spreader 1 is prevented from being tilted by the thermo-setting resin adhesive agent 9 provided on the planarized top surface of the disk-shaped heat radiation plate 1a of the heat spreader 1. As a result, the heat radiation effect is not deteriorated and the heat radiation properties are not variable. Furthermore, the thermo-setting resin adhesive agent 9 remains in the molded resin 10 but does not reside on the cavity of the die.

In this embodiment, the heat spreader 1 applied with the thermosetting resin adhesive agent 9, and the applied thermosetting resin adhesive agent is thermo-set before the lead frame mounted with the semiconductor device thereon is then placed over the bottom die prior to the resin injection process. As a modification, it is, however, possible for obtaining the effect of the present invention that the heat spreader 1 applied with the thermosetting resin adhesive agent 9, and subsequently the lead frame mounted with the semiconductor device thereon is placed over the bottom die before the thermosetting process of the applied thermosetting resin adhesive agent is completed prior to the resin injection process.

In this embodiment, the heat spreader 1 has a disk-shape. As a modification, it is possible for obtaining the effect of the present invention that the heat spreader 1 has a different shape from the disk-shape, for example, rectangle-shape. It is further possible for obtaining the effect of the present invention to modify the shape of the splits 1b of the heat spreader and also the shape of the ridge, if provided.

In this embodiment, the suspension pins 8 are provided at four corners of the island 6. As a modification, it is possible for obtaining the effect of the present invention that the suspension pins 8 are provided at different parts of the island 6 from the four corners.

SEVENTH EMBODIMENT:

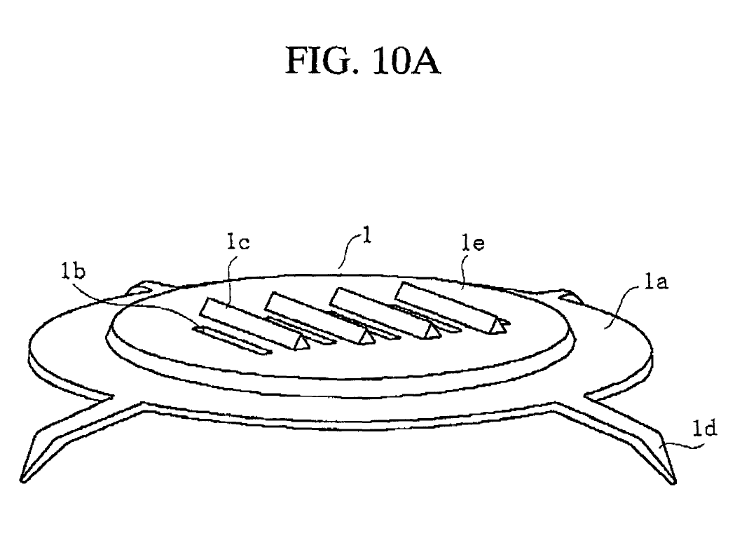

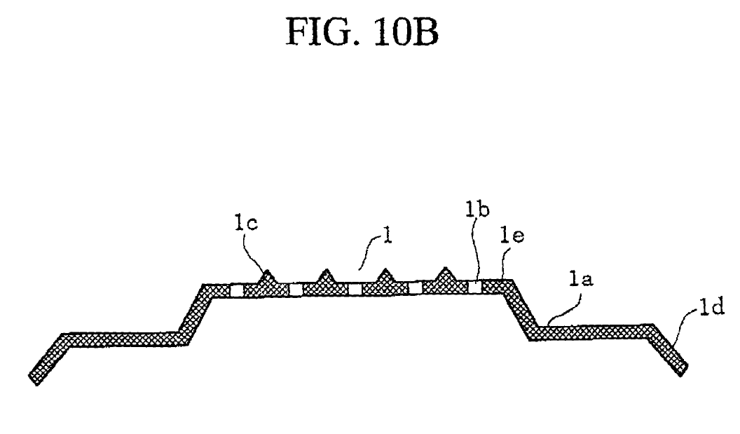

A seventh embodiment according to the present invention will be described in detail with reference to the drawings. FIG. 10A is a schematic perspective view illustrative of a novel drop-in-heat spreader to be used for a resin-encapsulated semiconductor device in a seventh embodiment in accordance with the present invention. FIG. 10B is a cross sectional view illustrative of a novel drop-in-heat spreader to be used for a resin-encapsulated semiconductor device in a seventh embodiment in accordance with the present invention. A drop-in-heat spreader 1 comprises a disk-shaped heat radiation plate 1a having four extension foots 1d which radially and downwardly extend from a circumferential part of the disk-shaped heat radiation plate 1a. The disk-shaped heat radiation plate 1a further has a disk-shaped elevated center region 1e which is higher in level than the disk-shaped heat radiation plate 1a. The disk-shaped elevated center region 1e extends over the disk-shaped heat radiation plate 1a, except on the peripheral region of the disk-shaped heat radiation plate 1a, so that the peripheral region of the heat spreader 1 is leveled down. The disk-shaped elevated center region 1e further has alternating alignments of slits 1b and ridged projections 1c, wherein the slits and the ridged projections extend in parallel to each other and are aligned alternatively.

If the above novel heat spreader is applied to the resin-encapsulated semiconductor device, the following effects can be obtained. The disk-shaped elevated center region 1e is higher in level than the disk-shaped heat radiation plate 1a and extends over the disk-shaped heat radiation plate 1a, except on the peripheral region of the disk-shaped heat radiation plate 1a, so that the peripheral region of the heat spreader 1 is leveled down. The heat spreader 1 is dropped into the cavity of the bottom die. A lead frame, on which a semiconductor device is mounted, is placed on the bottom die. A top die is moved so that the top die is made close to the bottom die, whereby the top and bottom dies are clamped. A resin is injected into the each cavity for resin-encapsulation to the semiconductor device. A curing process for curing the resin is carried out. The lead frame is cut and shaped to complete the resin-molded semiconductor device. As described above, the disk-shaped elevated center region 1e is higher in level than the disk-shaped heat radiation plate 1a and extends over the disk-shaped heat radiation plate 1a, except on the peripheral region of the disk-shaped heat radiation plate 1a, so that the peripheral region of the heat spreader 1 is leveled down, whereby a distance between the disk-shaped heat radiation plate 1a or the heat spreader 1 and the inner leads 3 is enlarged by the disk-shaped elevated center region 1e of the heat spreader 1.

When the resin is injected into the cavity for encapsulation to the semiconductor device mounted on the island which is supported over the heat spreader 1, the resin flow forces the heat spreader 1, so that the heat spreader 1 with the island and the semiconductor device is moved upwardly. However, the disk-shaped elevated center region 1e is higher in level than the disk-shaped heat radiation plate 1a and extends over the disk-shaped heat radiation plate 1a, except on the peripheral region of the disk-shaped heat radiation plate 1a, so that the peripheral region of the heat spreader 1 is leveled down, whereby a distance between the disk-shaped heat radiation plate 1a or the heat spreader 1 and the inner leads 3 is enlarged by the disk-shaped elevated center region 1e of the heat spreader 1. As a result, no short circuit is formed between the inner lead and the heat spreader. The height of the extension foots 1d of the heat spreader 1 is much larger than the distance between the upper surface of the heat spreader 1 to the island, for which reason an amount of the resin injected to the bottom space of the heat spreader 1 is much larger than an amount of the resin injected to the inter-space between the upper surface of the heat spreader 1 and the island. Even the heat spreader 1 has the plural slits 1b which allow the resin to pass through them, the heat spreader 1 is forced upwardly by the injected resin, whereby the upward movement of the heat spreader 1 is allows. However, the disk-shaped elevated center region 1e is higher in level than the disk-shaped heat radiation plate 1a and extends over the disk-shaped heat radiation plate 1a, except on the peripheral region of the disk-shaped heat radiation plate 1a, so that the peripheral region of the heat spreader 1 is leveled down, whereby a distance between the disk-shaped heat radiation plate 1a or the heat spreader 1 and the inner leads 3 is enlarged by the disk-shaped elevated center region 1e of the heat spreader 1. As a result, no short circuit is formed between the heat spreader 1 and the inner lead.

In this embodiment, the head spreader 1 has the ridged projections. As a modification, it is, however, possible for obtaining the effect of the present invention that the head spreader 1 is free of any projections such as ridged projections.

In this embodiment, the heat spreader 1 has a disk-shape. As a modification, it is possible for obtaining the effect of the present invention that the heat spreader 1 has a different shape from the disk-shape, for example, rectangle-shape. It is further possible for obtaining the effect of the present invention to modify the shape of the splits lb of the heat spreader and also the shape of the ridge, if provided.

In this embodiment, the suspension pins 8 are provided at four corners of the island 6. As a modification, it is possible for obtaining the effect of the present invention that the suspension pins 8 are provided at different parts of the island 6 from the four corners.

Whereas modifications of the present invention will be apparent to a person having ordinary skill in the art, to which the invention pertains, it is to be understood that embodiments as shown and described by way of illustrations are by no means intended to be considered in a limiting sense. Accordingly, it is to be intended to cover by claims all modifications which fall within the spirit and scope of the present invention.

What is claimed is:

1. A resin-encapsulated semiconductor device having inner leads and at least a heat spreader,
wherein at least an electrical insulator is provided between said inner leads and said heat spreader.

2. The resin-encapsulated semiconductor device as claimed in claim 1, wherein said electrical insulator comprises a sheet-shaped insulator which is provided on an inside region of a bottom surface of each of said inner leads, and said inside region faces to a peripheral region of said heat spreader.

3. The resin-encapsulated semiconductor device as claimed in claim 2, wherein said sheet-shaped insulator comprises a thermally stable and electrically insulative tape.

4. The resin-encapsulated semiconductor device as claimed in claim 1, wherein said electrical insulator comprises a sheet-shaped insulator which is provided on at least a peripheral region of said heat spreader, and said peripheral region faces to an inside region of a bottom surface of each of said inner leads.

5. The resin-encapsulated semiconductor device as claimed in claim 4, wherein said sheet-shaped insulator comprises a thermally stable and electrically insulative tape.

6. The resin-encapsulated semiconductor device as claimed in claim 1, wherein said electrical insulator comprises:
a first sheet-shaped insulator which is provided on an inside region of a bottom surface of each of said inner leads, and said inside region faces to a peripheral region of said heat spreader; and
a second sheet-shaped insulator which is provided on at least said peripheral region of said heat spreader.

7. The resin-encapsulated semiconductor device as claimed in claim 6, wherein said first sheet-shaped insulator comprises a thermally stable and electrically insulative tape.

8. The resin-encapsulated semiconductor device as claimed in claim 6, wherein said second sheet-shaped insulator comprises a thermally stable and electrically insulative tape.

9. A resin-encapsulated semiconductor device having inner leads and at least a heat spreader,
wherein suspension pins for suspending an island mounting a semiconductor device are formed to have a lower level than said inner leads.

10. A resin-encapsulated semiconductor device having inner leads and at least a heat spreader,
wherein said heat spreader has a fixing means for fixing said heat spreader to a cavity of a die.

11. The resin-encapsulated semiconductor device as claimed in claim 10, wherein said fixing means comprises an adhesive provided on a top of each of extension foots of said heat spreader.

12. The resin-encapsulated semiconductor device as claimed in claim 11, wherein said adhesive comprises a thermosetting resin adhesive.

13. A resin-encapsulated semiconductor device having inner leads and at least a heat spreader,
wherein said heat spreader has a fixing means for fixing said heat spreader to an island, on which a semiconductor device is mounted.

14. The resin-encapsulated semiconductor device as claimed in claim 10, wherein said fixing means comprises an adhesive provided on a top of each of projections of said heat spreader.

15. The resin-encapsulated semiconductor device as claimed in claim 14, wherein said adhesive comprises a thermosetting resin adhesive.

16. The resin-encapsulated semiconductor device as claimed in claim 10, wherein said fixing means comprises an adhesive provided on a planarized top surface of said heat spreader.

17. The resin-encapsulated semiconductor device as claimed in claim 16, wherein said adhesive comprises a thermosetting resin adhesive.

18. A resin-encapsulated semiconductor device having inner leads and at least a heat spreader,
wherein said heat spreader has an elevated center region having a light level than a peripheral region of said heat spreader.

19. A heat spreader for a resin-encapsulated semiconductor device having inner leads,
wherein at least an electrical insulator is provided between said inner leads and said heat spreader.

20. The heat spreader as claimed in claim 19, wherein said electrical insulator comprises a sheet-shaped insulator which is provided on at least a peripheral region of said heat spreader, and said peripheral region faces to an inside region of a bottom surface of each of said inner leads.

21. The heat spreader as claimed in claim 20, wherein said sheet-shaped insulator comprises a thermally stable and electrically insulative tape.

22. A heat spreader for a resin-encapsulated semiconductor device having inner leads,
wherein said heat spreader has a fixing means for fixing said heat spreader to a cavity of a die.

23. The heat spreader as claimed in claim 22, wherein said fixing means comprises an adhesive provided on a top of each of extension foots of said heat spreader.

24. The heat spreader as claimed in claim 23, wherein said adhesive comprises a thermosetting resin adhesive.

25. A heat spreader for a resin-encapsulated semiconductor device having inner leads,
wherein said heat spreader has a fixing means for fixing said heat spreader to an island, on which a semiconductor device is mounted.

26. The heat spreader as claimed in claim 25, wherein said fixing means comprises an adhesive provided on a top of each of projections of said heat spreader.

27. The heat spreader as claimed in claim 26, wherein said adhesive comprises a thermosetting resin adhesive.

28. The heat spreader as claimed in claim 25, wherein said fixing means comprises an adhesive provided on a planarized top surface of said heat spreader.

29. The heat spreader as claimed in claim 28, wherein said adhesive comprises a thermosetting resin adhesive.

30. A heat spreader for a resin-encapsulated semiconductor device having inner leads, wherein said heat spreader has an elevated center region having a light level than a peripheral region of said heat spreader.

31. A lead frame having a semiconductor device mounted on an island and inner leads for a resin-encapsulated semiconductor device having inner leads,
wherein at least an electrical insulator is provided an inside region of a bottom surface of each of said inner leads, and said inside region faces to a peripheral region of said heat spreader.

32. The lead frame as claimed in claim 31, wherein said sheet-shaped insulator comprises a thermally stable and electrically insulative tape.

33. A lead frame having a semiconductor device mounted on an island and inner leads for a resin-encapsulated semiconductor device having inner leads,
wherein suspension pins for suspending said island are formed to have a lower level than said inner leads.
